(19) United States
(12) Patent Application Publication
(10) Pub. No.: US 2013/0154126 A1
(43) Pub. Date: Jun. 20, 2013

(54) SEMICONDUCTOR DEVICE

(71) Applicant: Renesas Electronics Corporation, Kawasaki-shi (JP)

(72) Inventor: Kensuke HOTTA, Kawasaki-shi (JP)

(73) Assignee: Renesas Electronics Corporation, Kawasaki-shi (JP)

(21) Appl. No.: 13/711,484

(22) Filed: Dec. 11, 2012

(30) Foreign Application Priority Data
Dec. 14, 2011 (JP) 2011-273294

(51) Int. Cl. H01L 23/00

(52) U.S. Cl. CPC H01L 24/49
USPC 257/784

(57) ABSTRACT

A semiconductor device is provided which can change electrode pads of a semiconductor chip which are allocated to balls without any increase in the number of wires and without any change in a substrate. The semiconductor device includes a semiconductor chip having first and second electrode pads, and a package substrate on which the semiconductor chip is mounted. The package substrate includes a first stitch having a width larger than widths of first and second wires, a second stitch having a width larger than the widths of the first and second wires, a ball that can be coupled with an external, the first wire that couples the first stitch and the ball, and the second wire that couples the first stitch and the second stitch. A first bonding wire couples the first stitch and the first electrode pad, or the second stitch and the second electrode pad.

### CROSS-REFERENCE TO RELATED APPLICATIONS

The disclosure of Japanese Patent Application No. 2011-273294 filed on Dec. 14, 2011 including the specification, drawings and abstract is incorporated herein by reference in its entirety.

### BACKGROUND The present invention relates to a semiconductor device, and more particularly to a semiconductor device suitable for coupling to an external LSI.

A ball arrangement of an LSI package is determined, for example, taking wiring to the external LSI into account. After the ball arrangement of the LSI package has been determined, the arrangement cannot be normally changed. Accordingly, when the external LSI per se is changed, or the specification of the external LSI is changed, there is a possibility that wiring between an LSI package and the external LSI is congested depending on the ball arrangement of the LSI packet.

In recent years, ball pitches (arrangement intervals of the balls) of the LSI package are reduced, and the number of package substrate layers such as PCB substrates is also reduced. Further, a configuration on the substrate is changed according to each client. As a result, the wiring between the LSI package and the external LSI is further liable to be congested. For that reason, even when the external LSI has been changed, the wiring congestion between the LSI package and the external LSI is required to be suppressed as much as possible.

The related art is disclosed in Japanese Unexamined Patent Publication No. 2002-237567 and Japanese Unexamined Patent Publication No. 2010-103442.

FIG. 12 is a diagram illustrating a configuration of a semiconductor device disclosed in Japanese Unexamined Patent Publication No. 2002-237567. A semiconductor device of a related art illustrated in FIG. 12 is a package in which a stacked multichip (first chip 3 and second chip 4) is mounted on a substrate. In the semiconductor device illustrated in FIG. 12, auxiliary stitches 9, 10, 16, 17, and 18 are formed on an insulating layer 2 of a substrate 1 as redundant stitches aside from normal stitches. The auxiliary stitches 9 and 10 are coupled with each other by a jump wire 11. A pad A on the first chip 3 is wire-bonded to a stitch 6 through a wire 5, and a pad A on the second chip 4 is wire-bonded to a stitch 8 through a wire 7. Further, the stitch 6 is wired to the auxiliary stitch 9, and the stitch 8 is wired to the auxiliary stitch 10.

With the above configuration, even when the semiconductor chip is changed to another having a different pad arrangement, this change can be flexibly dealt with by one kind of substrate without occurrence of cross-wire.

In addition, Japanese Unexamined Patent Publication No. 2010-103442 discloses a mounting substrate for electronic components including a substrate having a mounting surface on which a mounting area of electronic components is provided, a plurality of external electrodes arrayed on an edge of the substrate, a plurality of first electrode pads for wire bonding arrayed outside of the mounting area on the mounting surface, a plurality of second electrode pads for flip chip arrayed inside of the mounting area on the mounting surface, a first wiring part that couples the first electrode pads and the external electrodes in a one-to-one manner, and a second wiring part that couples the first electrode pads and the second electrode pads in a one-to-one manner. The second wiring part couples the first electrode pads and the second electrode pads which have an inverted positional relationship in a front-rear direction of the substrate.

### SUMMARY

However, in the semiconductor device illustrated in FIG. 12, because wire bonding is required between the respective auxiliary stitches on the substrate, there arises such a problem that the number of wires increases. Further, a coupling direction of the wire bonding between the respective auxiliary stitches is different from a coupling direction of the wire bonding between the pads of the semiconductor chip and the normal stitches. This leads to such a problem that manufacturing processes are increased.

According to one aspect of the present invention, there is provided a semiconductor device including: a semiconductor chip having first and second electrode pads; and a package substrate on which the semiconductor chip is mounted, in which the package substrate includes first and second electrodes, a first external electrode that can be coupled with an external, a first wire that couples the first electrode and the first external electrode, and a second wire that couples the first electrode and the second electrode, and in which the package substrate further includes a first bonding wire that couples the first electrode and the first electrode pad, or the second electrode and the second electrode pad.

According to another aspect of the present invention, there is provided a semiconductor device including: a semiconductor chip having first and second electrode pads; and a package substrate on which the semiconductor chip is mounted, in which the package substrate includes a first electrode having a length corresponding to an arrangement interval between the first electrode pad and the second electrode pad, a first external electrode that can be coupled with an external, and a first wire that couples the first electrode and the first external electrode, and in which the package substrate further includes a first bonding wire that couples the first electrode and the first electrode pad, or the first electrode and the second electrode pad.

With the above-mentioned circuit configuration, the electrode pads of the semiconductor chip which are allocated to the balls can be changed without any increase in the number of wires as compared with the related art. With the use of this semiconductor device, for example, even if the external LSI is changed, there is no need to purposely change the substrate for the purpose of reducing the wiring congestion.

According to the aspects of the present invention, there can be provided the semiconductor device that can change the electrode pads of the semiconductor chip which are allocated to the balls without any increase in the number of wires as compared with the related art.

### BRIEF DESCRIPTION OF THE DRAWINGS

FIG. 1A is a plan view illustrating a part of a semiconductor device according to a first embodiment of the present invention;

FIG. 1B is a plan view illustrating a part of the semiconductor device according to the first embodiment of the present invention;

FIG. 2 is a cross-sectional view illustrating the semiconductor device according to the first embodiment of the present invention;

FIG. 3 is a plan view illustrating a semiconductor device according to a first modified example of the first embodiment of the present invention;

FIG. 4 is a plan view illustrating a semiconductor device according to a second modified example of the first embodiment of the present invention;

FIG. 5 is a plan view illustrating a semiconductor device according to a third modified example of the first embodiment of the present invention;

FIG. 6 is a plan view illustrating a part of a semiconductor device according to a second embodiment of the present invention;

FIG. 7 is a plan view illustrating a semiconductor device according to a modified example of the second embodiment of the present invention;

FIG. 8 is a diagram illustrating an overall configuration of a semiconductor device to which the present invention is applied;

FIG. 9 is a plan view illustrating a part of a semiconductor device according to a third embodiment of the present invention;

FIG. 10A is a plan view illustrating a part of a semiconductor device according to a fourth embodiment of the present invention;

FIG. 10B is a plan view illustrating a part of the semiconductor device according to the fourth embodiment of the present invention;

FIG. 11A is a diagram illustrating a problem with a related art;

FIG. 11B is a diagram illustrating the problem with the related art; and

FIG. 12 is a diagram illustrating a semiconductor device of a related art.

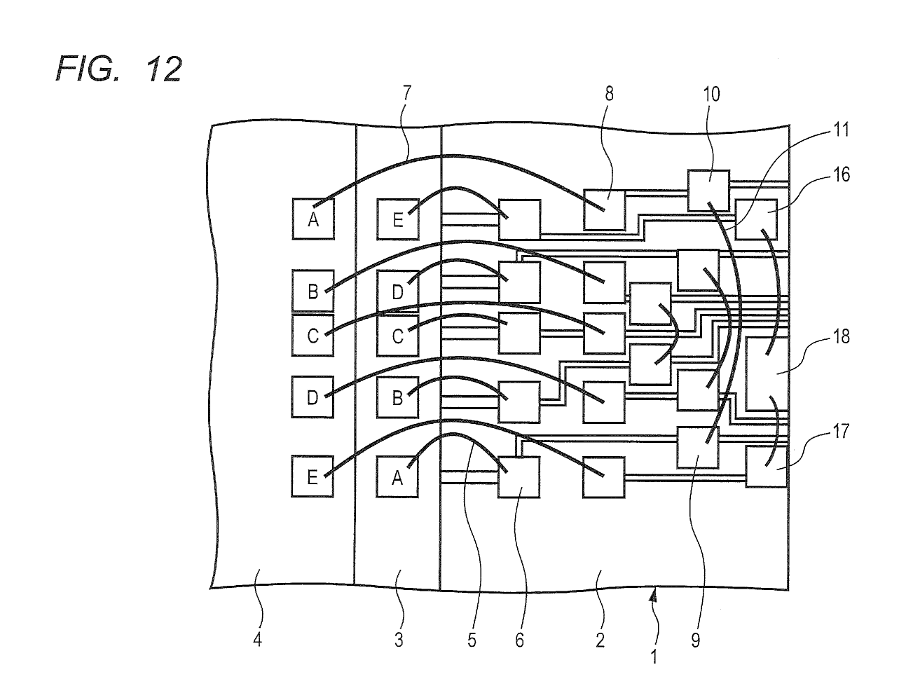

### DETAILED DESCRIPTION

Embodiments of the present invention will be described below with reference to the accompanying drawings. Since the drawings are simplified, the technical scope of the present invention is not to be narrowly interpreted on the basis of the illustration of the drawings. The same elements are denoted by identical reference numerals or symbols, and a repetitive description will be omitted.

Embodiments described below will be described by dividing into a plurality of sections or further embodiments when required as a matter of convenience. However, these sections or further embodiments are not irrelevant to each other unless otherwise specified, and one of them relates to a modification example, details, a supplementary explanation, or the like that includes the entire or a part of the others.

Also, in the following embodiments, when referring to the number elements (including the number of pieces, values, amounts, ranges, or the like), the number of elements is not limited to a specific number unless otherwise specified or except the case where the number is apparently limited to a specific number in principle. The number may be larger or smaller than a specific number.

Further, in the following embodiments, it goes without saying that the components (including element steps etc.) are not always indispensable unless otherwise specified or except the case where the components are apparently indispensable in principle. Similarly, in the following embodiments, when the shape of the components, the positional relation thereof, and the like are mentioned, the substantially approximate and similar shapes and the like are included therein unless otherwise specified or except the case where it can be thought that they are apparently excluded in principle. This condition is also applicable to the numerical value and the range described above.

### First Embodiment

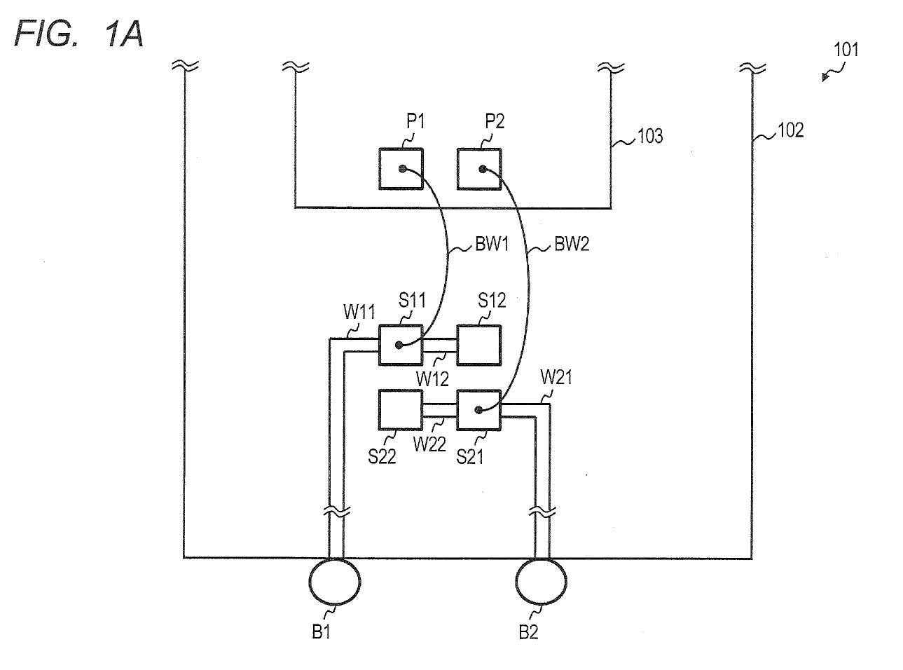

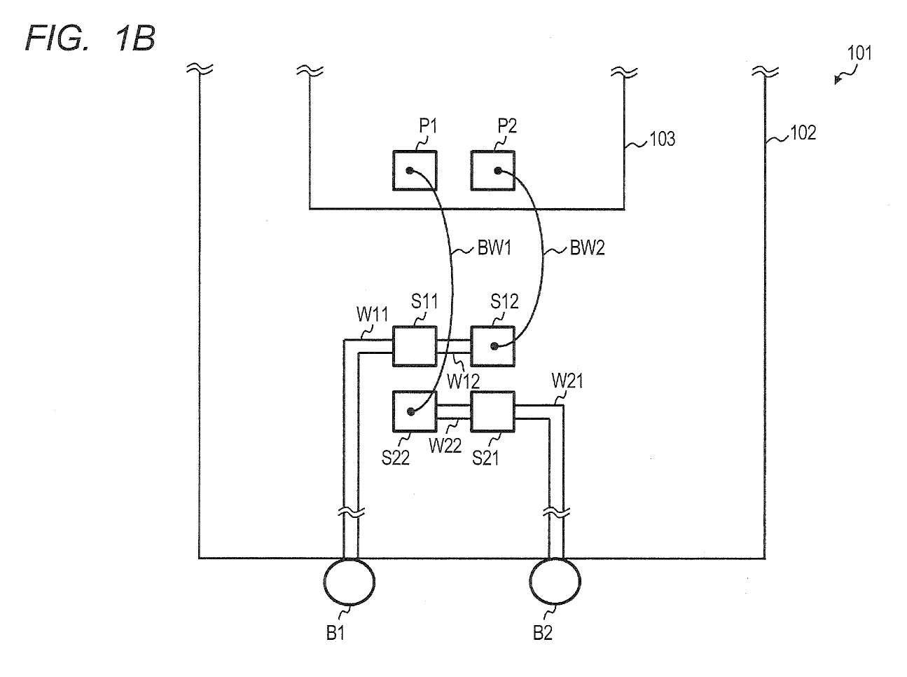

FIG. 1A is a plan view illustrating a part of a semiconductor device 101 according to a first embodiment of the present invention. The semiconductor device 101 according to this embodiment can change electrode pads of a semiconductor chip which are allocated to balls which are external balls with only a simple change in a coupling target of a bonding wire without allowing bonding wires to intersect with each other. In this situation, there is no need to newly add a bonding wire unlike the related art. For that reason, the semiconductor device 101 according to this embodiment can change the electrode pads of the semiconductor chip which are allocated to the balls without any increase in the number of wires. With the use of the semiconductor device, for example, even if an external LSI is changed, there is no need to purposely change the package substrate for the purpose of reducing the wiring congestion. Hereinafter, the first embodiment according to the present invention will be described in detail.

### First Plan View of Semiconductor Device 101

As illustrated in FIG. 1A, the semiconductor device 101 includes a package substrate 102, and a semiconductor chip 103 disposed on the package substrate 102. On the semiconductor chip 103 are arranged an electrode pad (first electrode pad) P1 and an electrode pad (second electrode pad) P2 along an outer periphery of the semiconductor chip 103. In an example of FIG. 1A, the electrode pad P1 and the electrode pad P2 are arranged in order from a left side toward a right side of a paper plane. In fact, a plurality of electrode pads not shown is arranged along an outer periphery of the semiconductor chip 103 aside from the electrode pads P1 and P2. Hereinafter, a description will be given of the electrode pads P1, P2, and peripheral circuits associated with the electrode pads P1 and P2.

On the package substrate 102, an electrode (first electrode, hereinafter referred to simply as “stitch”) S11 and an auxiliary stitch (second electrode) S12 are arranged outside of the semiconductor chip 103. More specifically, the stitch S11 is arranged to face the electrode pad P1 on the semiconductor chip 103 with one side (side interposed between the electrode pads and the stitches) X of the semiconductor chip 103 as an axis. The stitch S12 is arranged to face the electrode pad P2 on the semiconductor chip 103 with the one side X of the semiconductor chip 103 as the axis. In the example of FIG. 1A, the stitches S11 and S12 are arranged in parallel to the side X of the semiconductor chip 103 like the electrode pads P1 and P2.

Also, on the package substrate 102, a stitch (third electrode) S21 and an auxiliary stitch (fourth electrode) S22 are arranged at positions farther from the semiconductor chip 103 than the stitches S11 and S12, outside of the semiconductor chip 103. More specifically, the stitch S21 is arranged to face the electrode pad P2 at a position farther from the semiconductor chip 103 than the stitch S12 with the side X of the semiconductor chip 103 as the axis. The stitch S22 is arranged to face the electrode pad P1 at a position farther from the semiconductor chip 103 than the stitch S11 with the side X of the semiconductor chip 103 as the axis. In the example of FIG. 1A, the stitches S21 and S22 are arranged in parallel to the side X of the semiconductor chip 103 as with the electrode pads P1, P2, and the stitches S11, S12.

That is, in the example of FIG. 1A, the electrode pad P1 and the stitches S11, S22 are arranged in alignment in a direction (longitudinal direction of the paper plane) perpendicular to the Side X of the semiconductor chip 103. Also, the electrode pad P2 and the stitches S12, S21 are arranged in alignment in the direction (longitudinal direction of the paper plane) perpendicular to the side X of the semiconductor chip 103.

Further, the package substrate 102 is provided with a ball (first external electrode) B1 and a ball (second external electrode) B2 which can be coupled with an external circuit. For example, the balls B1 and B2 are attached on a rear side of the package substrate 102 in an array together with a plurality of other balls.

The stitch S11 and the auxiliary stitch S12 are coupled with each other through a wire (second wire) W12 arranged on the package substrate 102. Also, the stitch S11 and the ball B1 which is an external electrode are coupled with each other through a wire (first wire) W11 arranged on the package substrate 102.

Also, the stitch S21 and the auxiliary stitch S22 are coupled with each other through a wire (fourth wire) W22 arranged on the package substrate 102. Also, the stitch S21 and the ball 32 which is an external electrode are coupled with each other through a wire (third wire) W21 arranged on the package substrate 102.

Further, in the example of FIG. 1A, the electrode pad P1 on the semiconductor chip 103 and the stitch S11 are coupled with each other through a bonding wire BW1. The electrode pad P2 on the semiconductor chip 103 and the stitch S21 are coupled with each other through a bonding wire BW2. That is, in the example of FIG. 1A, the electrode pad P1 on the semiconductor chip 103 is allocated (electrically coupled) to the ball 31, and the electrode pad P2 on the semiconductor chip 103 is allocated (electrically coupled) to the ball B2.

### Cross-Section of Semiconductor Device 101

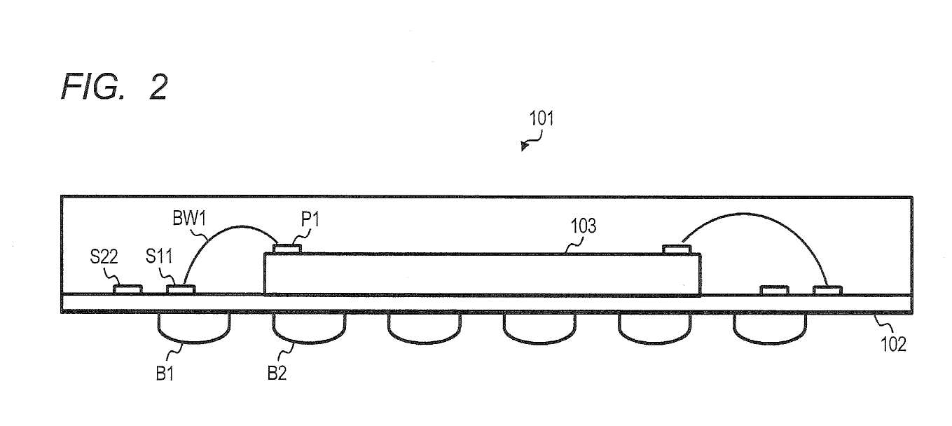

FIG. 2 is a cross-sectional view illustrating the semiconductor device 101 illustrated in FIG. 1A. As illustrated in FIG. 2, the semiconductor chip 103 is disposed on the package substrate (interposer) 102. The electrode pad P1 is arranged on an upper surface of the semiconductor chip 103. On the package substrate 102, the stitch S11 is arranged to face the electrode pad P1 with the side (side interposed between the electrode pads and the stitches) X of the semiconductor chip 103 as the axis. On the package substrate 102, the stitch S22 is arranged to face the electrode pad P1 at a position farther from the semiconductor chip 103 than the stitch S11 with the side X of the semiconductor chip 103 as the axis. The electrode pad P1 and the stitch S11 are coupled with each other through the bonding wire BW1. The electrode pad P2, the auxiliary stitch S12, and the stitch S21 not shown are also arranged in the same manner as that of the electrode pad P1, the stitch S11, and the auxiliary stitch S22, respectively. The electrode pad P2 and the stitch S21 are coupled with each other through the bonding wire BW2 (not shown).

Further, the balls B1 and B2 which are the external electrodes are disposed on a rear surface of the package substrate 102. Although not illustrated in FIG. 2, as described above, the ball B1 and the stitch S11 are coupled with each other through the wire W11, and the stitch S11 and the stitch S12 are coupled with each other through the wire W12. Also, as described above, the ball B2 and the stitch S21 are coupled with each other through the wire W21, and the stitch S21 and the stitch S22 are coupled with each other through the wire W22. In this way, the electrode pad P1 on the semiconductor chip 103 is allocated to the ball B1, and the electrode pad P2 on the semiconductor chip 103 is allocated to the ball B2.

### Second Plan View of Semiconductor Device 101

FIG. 1B is a plan view illustrating an example in which the coupling targets of the bonding wires BW1 and BW2 in the semiconductor device 101 illustrated in FIG. 1A are changed. In the semiconductor device 101 illustrated in FIG. 1B, the electrode pad P1 and the auxiliary stitch S22 are coupled with each other through the bonding wire BW1. Also, the electrode pad P2 and the auxiliary stitch S12 are coupled with each other through the bonding wire BW2. The other configurations of the semiconductor device 101 illustrated in FIG. 1B are identical with those in the semiconductor device 101 illustrated in FIG. 1A, and therefore a repetitive description thereof will be omitted.

In an example of FIG. 1B, as a substitute for the electrode pad P1, the electrode pad P2 is allocated (electrically coupled) to the ball B1, and as a substitute for the electrode pad P2, the electrode pad P1 is allocated (electrically coupled) to the ball B2.

As illustrated in FIGS. 1A and 1B, the coupling target of the bonding wire BW1 is not limited to the stitch S11, but can be also changed to the auxiliary stitch S22 . The coupling target of the bonding wire BW2 is not limited to the stitch S21, but can be also changed to the stitch S12 . For that reason, the electrode pads P1 and P2 on the semiconductor chip 103 which are allocated to the balls B1 and B2 can be changed by merely changing the coupling targets of the bonding wires BW1 and BW2.

The bonding wires that are coupled with the stitches (S11, S12) electrically coupled with the ball B1 are also called “first bonding wires”. That is, the bonding wire BW1 coupled between the electrode pad P1 and the stitch S11, and the bonding wire BW2 coupled between the electrode pad P2 and the stitch S12 are also called “first bonding wires”. The electrode pad P1 and the stitch S11, or the electrode pad P2 and the auxiliary stitch S12 are coupled by the first bonding wire.

The bonding wires that are coupled with the stitches (S21, S22) electrically coupled with the ball B2 are also called “second bonding wires”. That is, the bonding wire BW1 coupled between the electrode pad P1 and the stitch 22, and the bonding wire BW2 coupled between the electrode pad P2 and the stitch S21 are also called “second bonding wires”. The electrode pad P1 and the stitch S22, or the electrode pad P2 and the stitch S21 are coupled by the second bonding wire.

The first and second bonding wires are coupled with the respective different electrode pads.

In the examples of FIGS. 1A and 1B, as described above, the electrode pad P1 and the stitches S11, S22 are arranged in alignment in a direction (longitudinal direction of the paper plane) perpendicular to the side X of the semiconductor chip 103. Also, the electrode pad P2 and the stitches S12, S21 are arranged in alignment in the direction (longitudinal direction of the paper plane) perpendicular to the side X of the semiconductor chip 103. With the above configuration, the coupling targets of the bonding wires BW1 and BW2 can be changed without allowing the bonding wires BW1 and BW2 to intersect with each other.

In this way, the semiconductor device 101 according to this embodiment can change the electrode pads P1 and P2 of the semiconductor chip 103 which are allocated to the balls B1 and B2 which are external balls with only a simple change in the coupling targets of the bonding wires BW1 and BW2 without allowing the bonding wires BW1 and BW2 to intersect with each other. In this situation, there is no need to newly add a bonding wire unlike the related art. For that reason, the semiconductor device 101 according to this embodiment can change the electrode pads P1 and P2 of the semiconductor chip 103 which are allocated to the balls 31 and B2 without any increase in the number of wires. With the use of the semiconductor device, for example, even if the external LSI is changed, there is no need to purposely change the package substrate for the purpose of reducing the wiring congestion.

The above-mentioned respective stitches S11, S12, S21, and S22 have a width larger than that of the wires W11, W12, W21, and W22 so as to be easily coupled with the bonding wires BW1 and BW2, and are distinguished from the wires per se. Among the wires, a through-hole portion that couples a wire arranged on an upper layer of the substrate and a wire arranged on a lower layer thereof may have a width larger than the respective stitches. In the present specification, the width of the wires indicates the width of the wires arranged on one layer unless otherwise specified.

### First Modified Example of Semiconductor Device 101

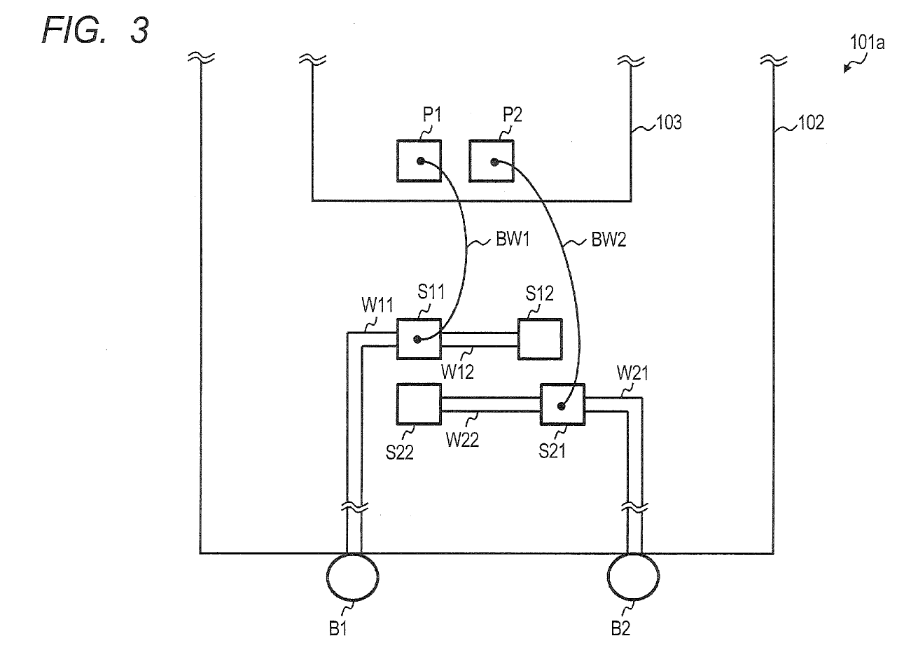

FIG. 3 is a plan view illustrating a modified example of the semiconductor device 101 illustrated in FIGS. 1A and 1B as a semiconductor device 101a. In the semiconductor device 101a illustrated in FIG. 3, as compared with the semiconductor device 101 illustrated in FIGS. 1A and 1B, the stitch S12 and the stitch S21 are not arranged to face the electrode pad P2 on the semiconductor chip 103 with the side (side interposed between the electrode pads and the stitches) X of the semiconductor chip 103 as the axis.

More specifically, the stitch S11 is arranged to face the electrode pad P1 on the semiconductor chip 103 with the side X of the semiconductor chip 103 as the axis. On the other hand, the auxiliary stitch S12 is arranged to be slightly displaced on a right side of the paper plane from a position facing the electrode pad P2 on the semiconductor chip 103. Accordingly, an interval between the stitch S11 and the auxiliary stitch S12 is larger than an interval between the electrode pad P1 and the electrode pad P2. The stitches S11 and S12 are arranged in parallel to the side X of the semiconductor chip 103 as with the electrode pads P1 and P2.

Also, the auxiliary stitch S22 is arranged to face the electrode pad P1 of the semiconductor chip 103 with the side X of the semiconductor chip 103 as the axis. On the other hand, the stitch S21 is arranged to be further displaced on the right side of the paper plane from a position facing the electrode pad P2 on the semiconductor chip 103. Accordingly, an interval between the stitch S21 and the auxiliary stitch S22 is larger than an interval is larger than the interval between the stitch 911 and the auxiliary stitch S12. The stitches S21 and S22 are arranged in parallel to the side X of the semiconductor chip 103 as with the electrode pads P1 and P2.

In the example of FIG. 3, the stitches S11 and S22 are disposed in the substantially same straight line. The other configurations of the semiconductor device 101a illustrated in FIG. 3 are identical with those of the semiconductor device 101 illustrated in FIG. 1A, and therefore a description thereof will be omitted.

Thus, the stitches (for example, stitch S21) and the auxiliary stitches (for example, auxiliary stitch S12) do not always need to be arranged to face the corresponding electrode pads (for example, electrode pad P2) with the side X of the semiconductor chip 103 as the axis. Unless the bonding wires (BW1, BW2) intersect with each other regardless of the coupling targets, positions at which the stitches are arranged can be appropriately changed. This arrangement of the stitches is particularly effective in a free area of the package substrate 102 such as four corners.

FIG. 3 exemplifies a case in which the auxiliary stitches S12 and S21 are arranged to be displaced from the position facing the electrode pad P2 with the side X of the semiconductor chip 103 as the axis. However, the present invention is not always limited to this configuration. For example, the present invention can be appropriately changed to a configuration in which the stitches S11 and S22 are arranged to be displaced from the position facing the electrode pad P1 with the side X of the semiconductor chip 103 as the axis.

### Second Modified Example of Semiconductor Device 101

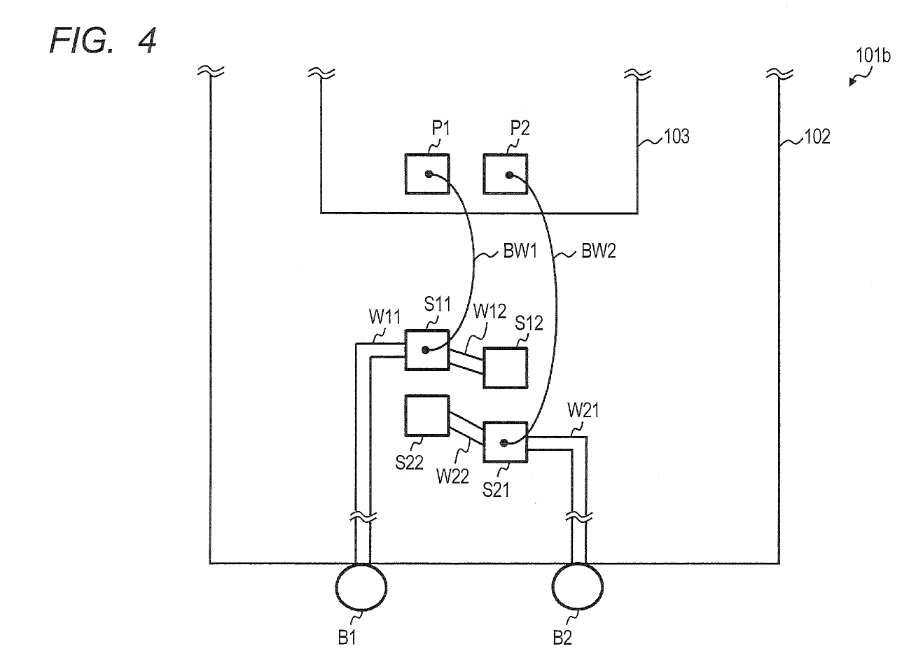

FIG. 4 is a plan view illustrating a second modified example of the semiconductor device 101 illustrated in FIGS. 1A and 1B as a semiconductor device 101b. In the semiconductor device 101b illustrated in FIG. 4, as compared with the semiconductor device 101 illustrated in FIGS. 1A and 1B, the stitch S11 and the stitch S12 are not arranged in parallel to the side X of the semiconductor chip 103. The stitch S21 and the stitch S22 are not arranged in parallel to the side X of the semiconductor chip 103. In other words, the stitches S11 and S12 are not arranged in parallel to the electrode pads P1 and P2. The stitches S21 and S22 are not arranged in parallel to the electrode pads P1 and P2.

More specifically, the stitch S11 is arranged to face the electrode pad P1 with the side X of the semiconductor chip 103 as the axis. On the other hand, the auxiliary stitch S12 is arranged to face the electrode pad P2 at a position farther from the semiconductor chip 103 than the stitch S11 with the side X of the semiconductor chip 103 as the axis. The auxiliary stitch S22 is arranged to face the electrode pad P1 with the side X of the semiconductor chip 103 as the axis. On the other hand, the stitch S21 is arranged to face the electrode pad P2 at a position farther from the semiconductor chip 103 than the stitch S22 with the side X of the semiconductor chip 103 as the axis.

The other configurations of the semiconductor device 101b illustrated in FIG. 4 are identical with those of the semiconductor device 101 illustrated in FIG. 1A, and therefore a description thereof will be omitted.

Thus, the stitches (for example, stitch S11) and the auxiliary stitches (for example, auxiliary stitch S12) coupled with that stitch through the wire do not always need to be arranged in parallel to the side X of the semiconductor chip 103. Unless the bonding wires (BW1, BW2) intersect with each other regardless of the coupling targets, positions at which the stitches are arranged can be appropriately changed. Also, the interval between each stitch and the auxiliary stitch (for example, stitches S11 and S12) does not need to be longer than the arrangement interval between the electrode pad P1 and the electrode pad P2.

### Third Modified Example of Semiconductor Device 101

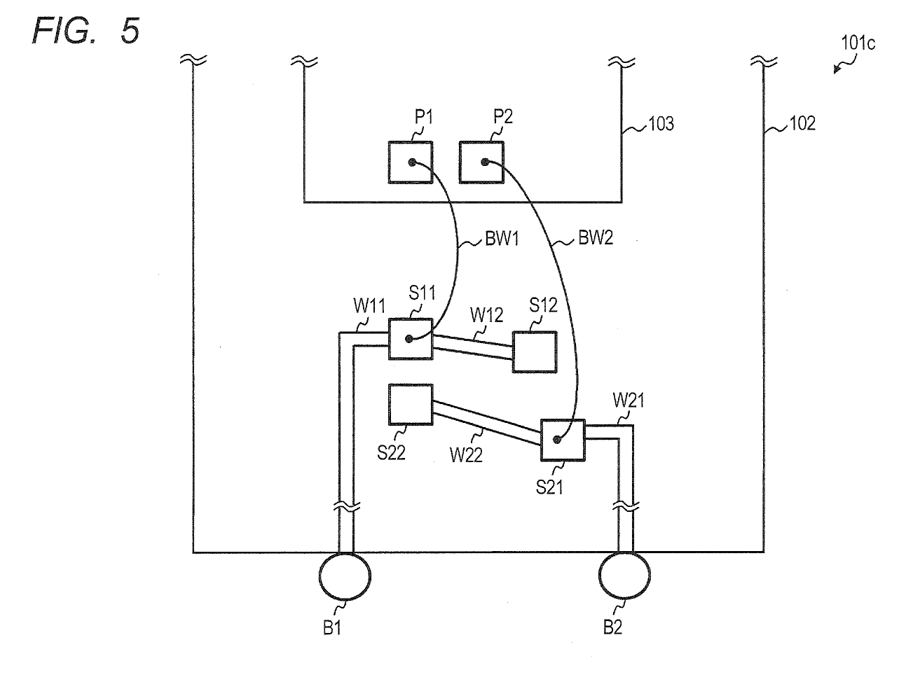

FIG. 5 is a plan view illustrating a third modified example of the semiconductor device 101 illustrated in FIGS. 1A and 1B as a semiconductor device 101c. The semiconductor device 101c illustrated in FIG. 5 is the combination of the first modified example illustrated in FIG. 3 with the second modified example illustrated in FIG. 4. The detailed description has already been described above, and will be omitted.

### Second Embodiment

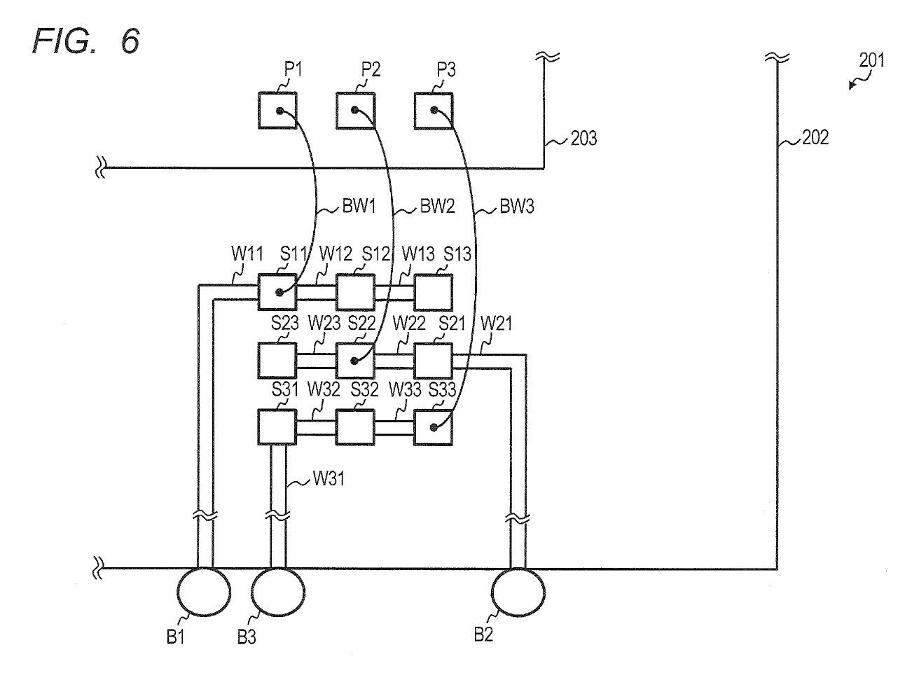

FIG. 6 is a plan view illustrating a part of a semiconductor device 201 according to a second embodiment of the present invention. The semiconductor device 201 illustrated in FIG. 6 is different from the semiconductor device 101 illustrated in FIGS. 1A and 1B in that two auxiliary stitches are provided for one stitch. Hereinafter, the second embodiment of the present invention will be described in more detail.

As illustrated in FIG. 6, the semiconductor device 201 includes a package substrate 202, and a semiconductor chip 203 disposed on the package substrate 202. On the semiconductor chip 203 are arranged the electrode pad P1, the electrode pad P2, and an electrode pad (third electrode pad) P3 along an outer periphery of the semiconductor chip 203. In an example of FIG. 6, the electrode pad P1, the electrode pad P2, and the electrode pad P3 are arranged in order from the left side toward the right side of the paper plane. In fact, a plurality of electrode pads not shown is arranged along the outer periphery of the semiconductor chip 203 aside from the electrode pads P1 to P3. Hereinafter, a description will be given of the electrode pads P1 to P3, and peripheral circuits associated with the electrode pads P1 to P3.

On the package substrate 202, the stitch S11, the auxiliary stitch S12, and a stitch (fifth electrode) S13 are arranged outside of the semiconductor chip 203. More specifically, the stitch S11 is arranged to face the electrode pad P1 on the semiconductor chip 203 with one side (side interposed between the electrode pads and the stitches) X of the semiconductor chip 203 as an axis. The stitch S12 is arranged to face the electrode pad P2 on the semiconductor chip 203 with the one side X of the semiconductor chip 203 as the axis. The stitch S13 is arranged to face the electrode pad P3 on the semiconductor chip 203 with the one side X of the semiconductor chip 203 as the axis. In the example of FIG. 6, the stitches S11 to S13 are arranged in parallel to the side X of the semiconductor chip 203 like the electrode pads P1 to P3.

Also, on the package substrate 202, the stitch S21 and the auxiliary stitches S22 and S23 are arranged at positions farther from the semiconductor chip 203 than the stitches S11 to S13, outside of the semiconductor chip 203. More specifically, the stitch S21 is arranged to face the electrode pad P3 at a position farther from the semiconductor chip 203 than the stitch S13 with the side X of the semiconductor chip 203 as the axis. The stitch S22 is arranged to face the electrode pad P2 at a position farther from the semiconductor chip 203 than the stitch S12 with the side X of the semiconductor chip 203 as the axis. The stitch S23 is arranged to face the electrode pad P1 at a position farther from the semiconductor chip 203 than the stitch S11 with the side X of the semiconductor chip 203 as the axis. In the example of FIG. 6, the stitches S21 to S23 are arranged in parallel to the side X of the semiconductor chip 203 as with the electrode pads P1 to P3.

Also, on the package substrate 202, a stitch S33 and auxiliary stitches S31 and S32 are arranged at positions farther from the semiconductor chip 203 than the stitches S21 to S23, outside of the semiconductor chip 203. More specifically, the stitch S31 is arranged to face the electrode pad P1 at a position farther from the semiconductor chip 203 than the stitch S23 with the side X of the semiconductor chip 203 as the axis. The stitch S32 is arranged to face the electrode pad P2 at a position farther from the semiconductor chip 203 than the stitch S22 with the side X of the semiconductor chip 203 as the axis. The stitch S33 is arranged to face the electrode pad P3 at a position farther from the semiconductor chip 203 than the stitch S21 with the side X of the semiconductor chip 203 as the axis. In the example of FIG. 6, the stitches S31 to S33 are arranged in parallel to the side X of the semiconductor chip 203 as with the electrode pads P1 to P3.

That is, in the example of FIG. 6, the electrode pad P1 and the stitches S11, S23, S31 are arranged in alignment in a direction (longitudinal direction of the paper plane) perpendicular to the side X of the semiconductor chip 203. The electrode pad P2 and the stitches S12, S22, S23 are arranged in alignment in the direction (longitudinal direction of the paper plane) perpendicular to the side X of the semiconductor chip 203. Also, the electrode pad P3 and the stitches S13, S21, S33 are arranged in alignment in the direction (longitudinal direction of the paper plane) perpendicular to the side X of the semiconductor chip 203.

Further, the package substrate 202 is provided with the balls (external electrodes) B1 to B3 which can be coupled with an external circuit. For example, the balls B1 to B3 are attached on a rear side of the package substrate 202 in an array together with a plurality of other balls.

The stitch S11 and the auxiliary stitch S12 are coupled with each other through the wire W12 arranged on the package substrate 202. The auxiliary stitch S12 and the auxiliary stitch S13 are coupled with each other through the wire (fifth wire) W13 arranged on the package substrate 202. Also, the stitch S11 and the ball B1 which is an external electrode are coupled with each other through the wire W11 arranged on the package substrate 202.

The auxiliary stitch S21 and the stitch S22 are coupled with each other through the wire W22 arranged on the package substrate 202. The stitch S22 and the auxiliary stitch S23 are coupled with each other through a wire W23 arranged on the package substrate 202. The auxiliary stitch S21 and the ball B2 which is the external electrode are coupled with each other through the wire W21 arranged on the package substrate 202.

The auxiliary stitch S31 and the auxiliary stitch S32 are coupled with each other through a wire W32 arranged on the package substrate 202. The auxiliary stitch S32 and the stitch S33 are coupled with each other through a wire W33 arranged on the package substrate 202. Also, the auxiliary stitch S31 and the ball B3 which is the external electrode are coupled with each other through a wire W31 arranged on the package substrate 202.

In the example of FIG. 6, the electrode pad P1 on the semiconductor chip 203 and the stitch S11 are coupled with each other through the bonding wire BW1. The electrode pad P2 on the semiconductor chip 203 and the stitch S22 are coupled with each other through the bonding wire BW2. The electrode pad P3 on the semiconductor chip 203 and the stitch S33 are coupled with each other through a bonding wire BW3. That is, in the example of FIG. 6, the electrode pad P1 on the semiconductor chip 203 is allocated (electrically coupled) to the ball B1, the electrode pad P2 on the semiconductor chip 203 is allocated (electrically coupled) to the ball B2, and the electrode pad P3 on the semiconductor chip 203 is allocated (electrically coupled) to the ball B3.

The coupling target of the bonding wire BW1 is not limited to the stitch S11, but can be also changed to the stitch S23 and the stitches S31. The coupling target of the bonding wire BW2 is not limited to the stitch S22, but can be also changed to the stitch S12 and the stitch S32. The coupling target of the bonding wire BW3 is not limited to the stitch S33, but can be also changed to the stitch S13 and the stitch S21. For that reason, the electrode pads P1 to P3 on the semiconductor chip 203 which are allocated to the balls B1 to B3 can be changed by merely changing the coupling targets of the bonding wires BW1 to BW3.

The bonding wires that are coupled with the stitches (S11 to S13) electrically coupled with the ball B1 are also called “first bonding wires” . That is, the bonding wire BW1 coupled between the electrode pad P1 and the stitch S11, the bonding wire BW2 coupled between the electrode pad P2 and the stitch S12, and the bonding wire BW3 coupled between the electrode pad P2 and the stitch S13 are also called “first bonding wires”. The electrode pad P1 and the stitch 511, the electrode pad P2 and the auxiliary stitch S12, or the electrode pad P3 and the auxiliary stitch S13, are coupled by the first bonding wire.

The bonding wires that are coupled with the stitches (S21 to S23) electrically coupled with the ball B2 are also called “second bonding wires”. That is, the bonding wire BW1 coupled between the electrode pad P1 and the stitch S23, the bonding wire BW2 coupled between the electrode pad P2 and the stitch 22, and the bonding wire BW3 coupled between the electrode pad P3 and the stitch S23 are also called “second bonding wires” . The electrode pad P1 and the stitch S23, the electrode pad P2 and the stitch S22, or the electrode pad P3 and the stitch S21, are coupled by the second bonding wire.

The bonding wires that are coupled with the stitches (S31 to S33) electrically coupled with the ball B3 are also called “fifth bonding wires”. That is, the bonding wire BW1 coupled between the electrode pad P1 and the stitch S31, the bonding wire BW2 coupled between the electrode pad P2 and the stitch 32, and the bonding wire BW3 coupled between the electrode pad P3 and the stitch S33 are also called “fifth bonding wires”. The electrode pad P1 and the stitch S31, the electrode pad P2 and the stitch S32, or the electrode pad P3 and the stitch S33, are coupled by the fifth bonding wire.

The first, second and fifth bonding wires are coupled with the respective different electrode pads.

In the example of FIG. 6, as described above, the electrode pad P1 and the stitches S11, S23, S31 are arranged in alignment in a direction (longitudinal direction of the paper plane) perpendicular to the side X of the semiconductor chip 203. The electrode pad P2 and the stitches S12, S22, S32 are arranged in alignment in the direction (longitudinal direction of the paper plane) perpendicular to the side X of the semiconductor chip 203. Also, the electrode pad P3 and the stitches S13, S21, S33 are arranged in alignment in the direction (longitudinal direction of the paper plane) perpendicular to the side X of the semiconductor chip 203. For that reason, the coupling targets of the bonding wires BW1 to BW3 can be changed without allowing the bonding wires BW1 to BW3 to intersect with each other.

In this way, the semiconductor device 201 according to this embodiment can change the electrode pads P1 to P3 of the semiconductor chip 203 which are allocated to the balls B1 to B3 which are external balls with only a simple change in the coupling targets of the bonding wires BW1 to BW3 without allowing the bonding wires BW1 to BW3 to intersect with each other. In this situation, there is no need to newly add a bonding wire unlike the related art. For that reason, the semiconductor device 201 according to this embodiment can change the electrode pads P1 to P3 of the semiconductor chip 203 which are allocated to the balls B1 to B3 without any increase in the number of wires. With the use of the semiconductor device, for example, even if the external LSI is changed, there is no need to purposely change the package substrate for the purpose of reducing the wiring congestion.

The above-mentioned respective stitches S11 to S13, S21 to S23, and S31 to S33 have a width larger than that of the wires W11 to W13, W21 to W23, and W31 to W33 so as to be easily coupled with the bonding wires BW1 to BW3, and are distinguished from the wires per se.

### Modified Example of Semiconductor Device 201

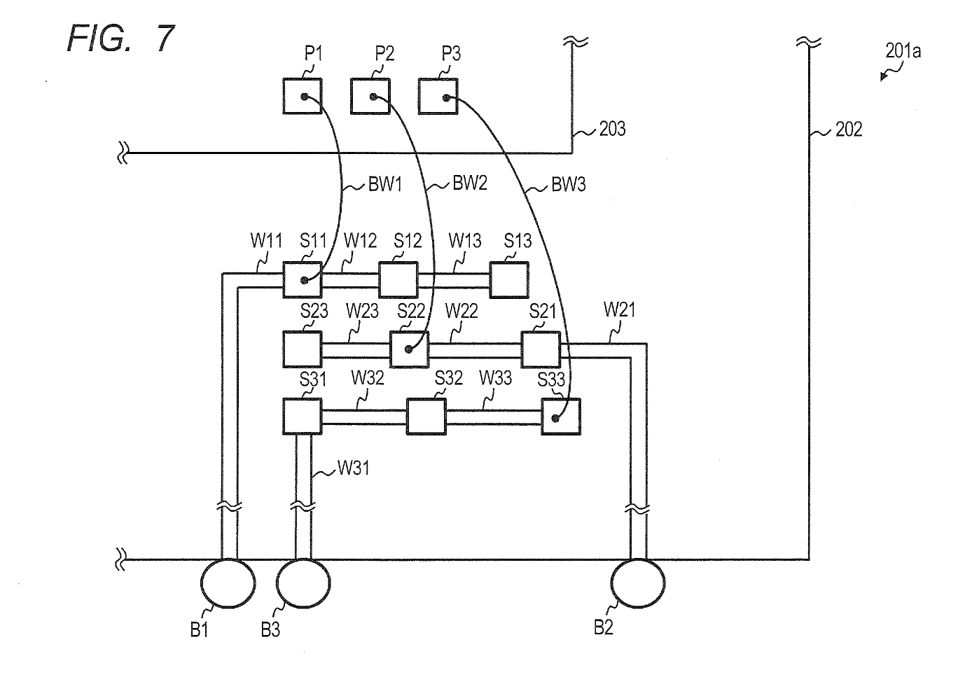

FIG. 7 is a plan view illustrating a modified example of the semiconductor device 201 illustrated in FIGS. 6 as a semiconductor device 201a. In the semiconductor device 201a illustrated in FIG. 7, as compared with the semiconductor device 201 illustrated in FIG. 6, the stitches S12, S22, and S32 are not arranged to face the electrode pad P2 on the semiconductor chip 203 with the side (side interposed between the electrode pads and the stitches) X of the semiconductor chip 203 as the axis. The stitches S13, S21, and S33 are not arranged to face the electrode pad P3 of the semiconductor chip 203 with the side X of the semiconductor chip 203 as the axis. The details are basically identical with those in the semiconductor device 101a illustrated in FIG. 3, and a description thereof will be omitted.

Thus, the stitches (for example, stitch S22) and the auxiliary stitches (for example, auxiliary stitch S32) do not always need to be arranged to face the corresponding electrode pads (for example, electrode pad P3) with the side X of the semiconductor chip 203 as the axis. Unless the bonding wires (BW1 to BW3) intersect with each other regardless of the coupling targets, positions at which the stitches are arranged can be appropriately changed. This arrangement of the stitches is particularly effective in a free area of the package substrate 102 such as four corners.

The present invention can be appropriately changed to a position at which another stitch (for example, stitch S11) is arranged without being limited to the example of FIG. 7.

In addition, as with the example of FIG. 4, the stitches S11 to S13, the stitches S21 to S23, and the stitches S31 to S33 do not always need to be arranged in parallel to the side X of the semiconductor chip 203. Unless the bonding wires (BW1 to BW3) intersect with each other regardless of the coupling targets, positions at which the stitches are arranged can be appropriately changed.

### Applied Case of the Invention

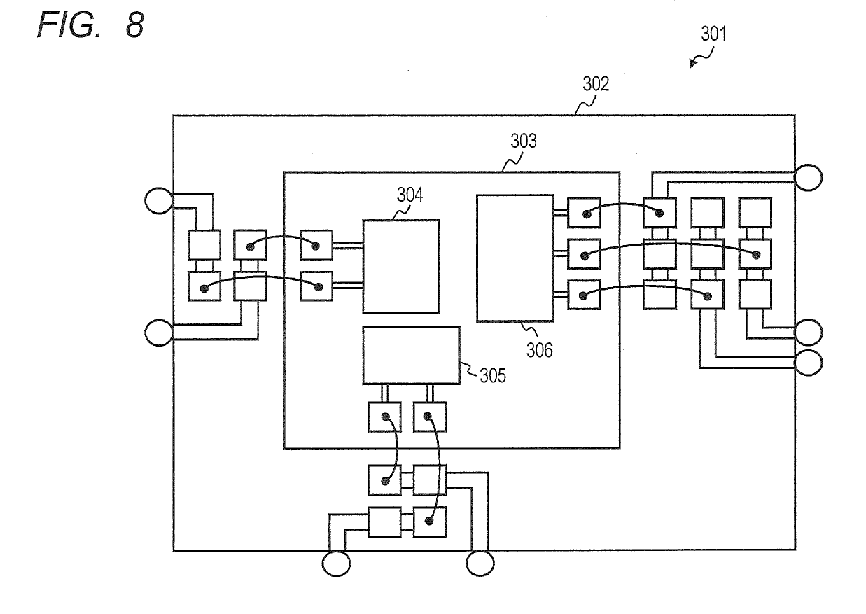

FIG. 8 is a diagram illustrating an overall configuration of a semiconductor device 301 to which the present invention is applied. In the semiconductor device 301 illustrated in FIG. 8, the configuration of the present invention is applied to each of functional blocks.

As illustrated in FIG. 8, the semiconductor device 301 includes a package substrate 302, and a semiconductor chip 303 disposed on the package substrate 302. For example, the semiconductor chip 303 is provided with a functional block that conducts video related processing (hereinafter referred to simply as “video system circuit”) 304, a functional block that conducts audio related processing (hereinafter referred to simply as “audio system circuit”) 305, and a functional block that conducts processing of a power supply system (hereinafter referred to simply as “power supply system circuit”) 306. The configuration (configuration in which the stitches and the auxiliary stitches which are arranged to face the electrode pads are wired to the electrode pads) of the present invention represented by FIGS. 1A, 1B, and 3. The configuration of the present invention is identical with the contents described in FIGS. 1A, 1B, and 3, and its description will be omitted.

When the configuration of the present invention is thus applied on the functional block basis, the number of auxiliary stitches can be reduced as compared with a case where the present invention is applied to the entire semiconductor device. For that reason, the space of the substrate can be effectively utilized.

### Third Embodiment

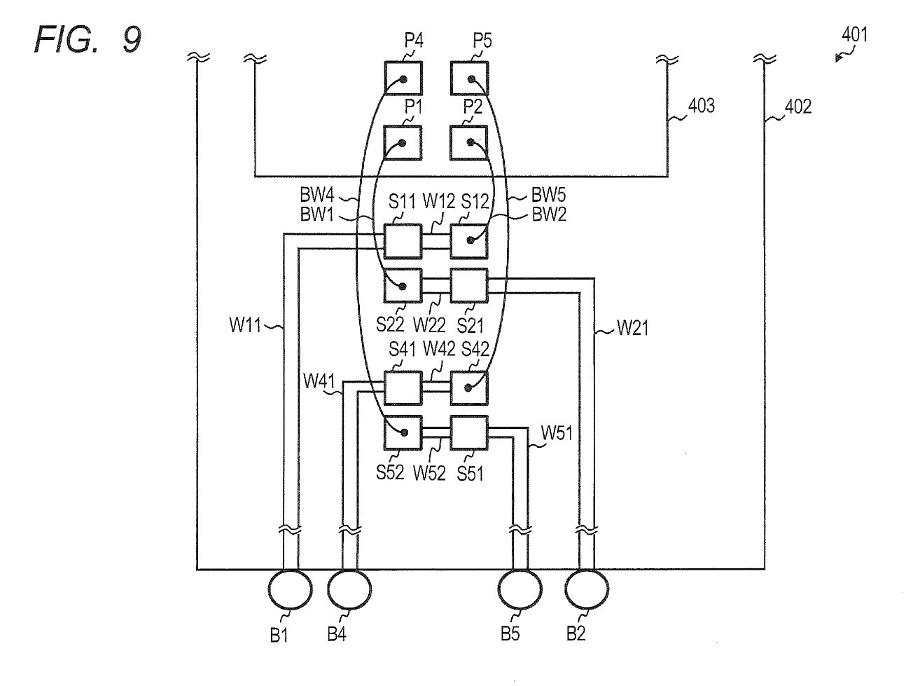

FIG. 9 is a plan view illustrating a part of a semiconductor device 401 according to a third embodiment of the present invention. In this embodiment, a description will be given of a case in which the present invention is applied to a semiconductor chip having multistage pads.

As illustrated in FIG. 9, the semiconductor device 401 includes a package substrate 402, and a semiconductor chip 403 disposed on the package substrate 402. On the semiconductor chip 403, the electrode pads 91 and P2 are arranged along an outer periphery of the semiconductor chip 403, and an electrode pad (fourth electrode pad) P4 and an electrode pad (fifth electrode pad) P5 are further arranged inside of the electrode pads P1 and P2.

On the package substrate 402, the stitch S12 and the auxiliary stitch S11 are arranged outside of the semiconductor chip 403. Also, on the package substrate 402, the stitch S22 and the auxiliary stitch S21 are arranged at positions farther from the semiconductor chip 403 than the stitches S11 and S12 outside of the semiconductor chip 403. The detailed description is identical with the contents described in FIG. 1A, and therefore will be omitted.

Further, on the package substrate 402, a stitch (seventh electrode) S42 and an auxiliary stitch (sixth electrode) S41 are arranged at positions farther from the semiconductor chip 403 than the stitches S21 and S22 outside of the semiconductor chip 403. Also, on the package substrate 402, a stitch S52 and an auxiliary stitch S51 are arranged at positions farther from the semiconductor chip 403 than the stitches S41 and S42 outside of the semiconductor chip 403. A relationship of the arrangement of the stitches S41, S42, S51, and S52 is identical with a relationship of the arrangement of the stitches S11, S12, S21, and S22.

In the example of FIG. 9, the stitches S11 and S22 are arranged to face the electrode pad P1 with the side (interposed between the electrode pads and the stitches) X of the semiconductor chip 403 as the axis. The stitches S12 and S21 are arranged to face the electrode pad P2 with the side X of the semiconductor chip 403 as the axis. The stitches S41 and S52 are arranged to face the electrode pad P4 with the side (interposed between the electrode pads and the stitches) X of the semiconductor chip 403 as the axis. The stitches S42 and S51 are arranged to face the electrode pad P5 with the side X of the semiconductor chip 403 as the axis. That is, in the example of FIG. 9, the electrode pads P4, P1 and the stitches S11, S22, S41, S52 are arranged in alignment in a direction (longitudinal direction of the paper plane) perpendicular to the side X of the semiconductor chip 403. Also, the electrode pads P5, P2 and the stitches S12, S21, S42, S51 are arranged in alignment in the direction (longitudinal direction of the paper plane) perpendicular to the side X of the semiconductor chip 103.

Further, the package substrate 402 is provided with the ball B1, a ball (third external electrode) B4, and a ball B5 which can be coupled with the external circuit. For example, the balls B1, B2, B4, and B5 are attached on a rear side of the package substrate 402 in an array together with a plurality of other balls.

The auxiliary stitch S11 and the stitch S12 are coupled with each other through the wire W12 arranged on the package substrate 402. The auxiliary stitch S11 and the ball B1 which is the external electrode are coupled with each other through the wire W11 arranged on the package substrate 402. The auxiliary stitch S21 and the stitch S22 are coupled with each other through the wire W22 arranged on the package substrate 402. The auxiliary stitch S21 and the ball B2 which is the external electrode are coupled with each other through the wire W21 arranged on the package substrate 402.

The auxiliary stitch S41 and the stitch S42 are coupled with each other through a wire (seventh wire) W42 arranged on the package substrate 402. The auxiliary stitch S41 and the ball B4 which is the external electrode are coupled with each other through a wire (sixth wire) W41 arranged on the package substrate 402. The auxiliary stitch S51 and the stitch 852 are coupled with each other through a wire W52 arranged on the package substrate 402. The auxiliary stitch S51 and the ball B5 which is the external electrode are coupled with each other through a wire W51 arranged on the package substrate 402.

In the example of FIG. 9, the electrode pad P1 on the semiconductor chip 403 and the stitch S22 are coupled with each other through the bonding wire BW1. The electrode pad P2 on the semiconductor chip 403 and the stitch S12 are coupled with each other through the bonding wire BW2. The electrode pad P4 on the semiconductor chip 403 and the stitch S52 are coupled with each other through a bonding wire BW4. The electrode pad P5 on the semiconductor chip 403 and the stitch S42 are coupled with each other through a bonding wire BW5. That is, in the example of FIG. 9, the electrode pad P2 on the semiconductor chip 403 is allocated to the ball B1, the electrode pad P1 on the semiconductor chip 403 is allocated to the ball B2, the electrode pad P5 on the semiconductor chip 403 is allocated to the ball B4, and the electrode pad P4 on the semiconductor chip 403 is allocated to the ball B5.

The coupling target of the bonding wire BW1 is not limited to the stitch S22, but can be also changed to the stitch S11 (further the stitches S41 and S52 if there is a free space). The coupling target of the bonding wire BW2 is not limited to the stitch S12, but can be also changed to the stitch S21 (further the stitches S42 and S51 if there is a free space). The coupling target of the bonding wire BW4 is not limited to the stitch S52, but can be also changed to the stitch S41 (further the stitches S11 and S22 if there is a free space). The coupling target of the bonding wire BW5 is not limited to the stitch S42, but can be also changed to the stitch S51 (further the stitches S12 and S21 if there is a free space) .

For that reason, the electrode pads P1, P2, P4, and P5 on the semiconductor chip 403 which are allocated to the balls B1, B2, 34, and BE can be changed by merely changing the coupling targets of the bonding wires BW1, BW2, BW4, and BW5.

The bonding wires that are coupled with the stitches (S41, S42) electrically coupled with the ball B4 are also called “third bonding wires”. That is, the bonding wire BW4 coupled between the electrode pad P4 and the stitch S41, and the bonding wire BW5 coupled between the electrode pad P5 and the stitch S42, are also called “third bonding wires”. The electrode pad P4 and the stitch S41, or the electrode pad P5 and the stitch S42, are coupled by the third bonding wire.

The bonding wires that are coupled with the stitches (S51, S52) electrically coupled with the ball B5 are also called “fourth bonding wires”. That is, the bonding wire BW4 coupled between the electrode pad P4 and the stitch S52, and the bonding wire BW5 coupled between the electrode pad P5 and the stitch S51, are also called “fourth bonding wires”. The electrode pad P4 and the stitch S52, or the electrode pad P5 and the stitch S51, are coupled by the fourth bonding wire.

The third and fourth bonding wires are coupled with the respective different electrode pads.

In the example of FIG. 9, as described above, the electrode pads P4, P1 and the stitches S11, S22, S41, S52 are arranged in alignment in a direction (longitudinal direction of the paper plane) perpendicular to the side X of the semiconductor chip 403. For that reason, the coupling targets of the bonding wires BW1 and BW2 can be changed without allowing the bonding wires BW1 and BW2 to intersect with each other. Also, the electrode pads P5, P2 and the stitches S12, S21, S42, S51 are arranged in alignment in a direction (longitudinal direction of the paper plane) perpendicular to the side X of the semiconductor chip 403. For that reason, the coupling targets of the bonding wires BW4 and BW5 can be changed without allowing the bonding wires BW4 and BW5 to intersect with each other. The bonding wires BW1, BW2, and the bonding wire BW4, BW5 are different from each other in the wire height, and therefore there arises no problem even if those wires intersect with each other.

In this way, even if the semiconductor chip of the multistage pads are mounted on the package substrate, the present invention can be applied to this configuration, and the same advantages as those in the other embodiments can be obtained. The respective stitches do not always need to be arranged to face the corresponding electrode pads with a lateral direction of the paper plane as the axis as in the other embodiments. Also, the stitches and the auxiliary stitches do not always need to be arranged in parallel to the side X of the semiconductor chip as in the other embodiments. If the bonding wires (BW1, BW2, BW4, BW5) do not intersect with each other regardless of the coupling targets, the position at which the stitches are arranged can be appropriately changed.

### Fourth Embodiment

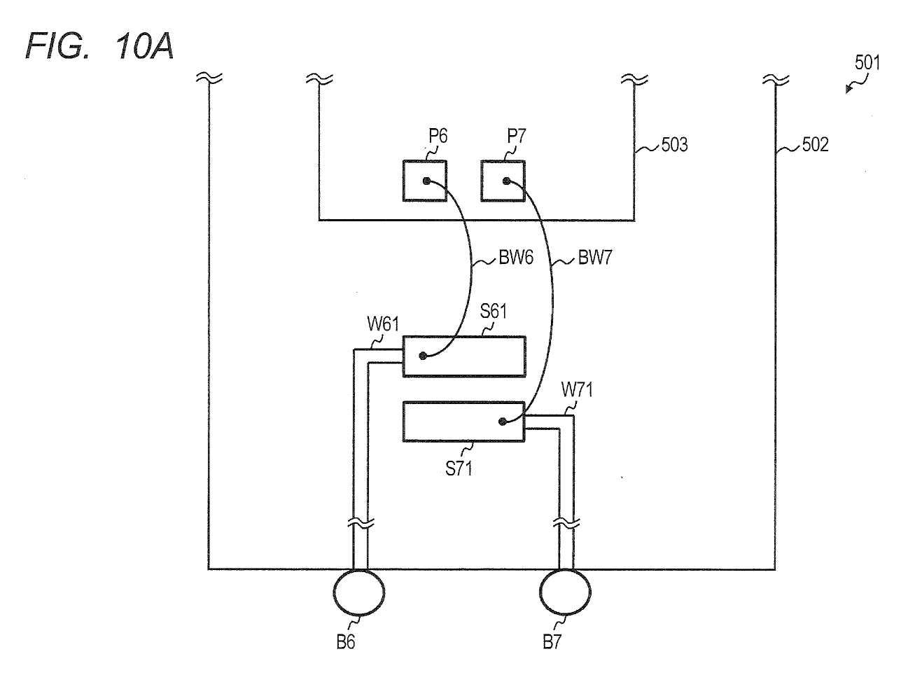

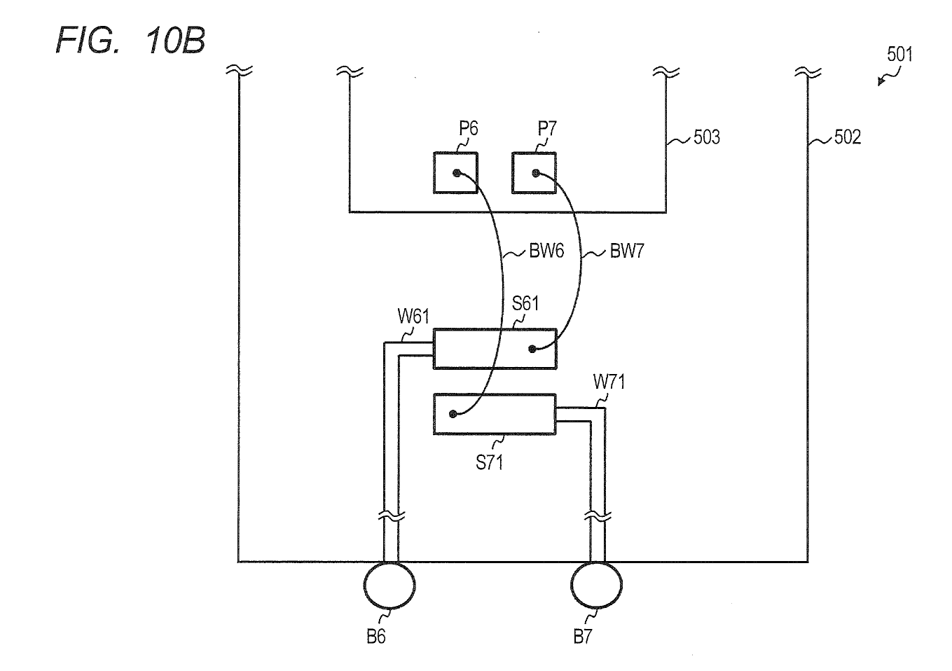

FIGS. 10A and 10B are plan views illustrating a part of a semiconductor device 501 according to a fourth embodiment of the present invention. The semiconductor device 501 illustrated in FIGS. 10A and 10B are different in the shape of the stitches from the semiconductor device 101 illustrated in FIGS. 1A and 1B. Hereinafter, the fifth embodiment of the present invention will be described in detail with reference to FIG. 10A.

As illustrated in FIG. 10A, the semiconductor device 501 includes a package substrate 502 and a semiconductor chip 503. Electrode pads P6 and P7 are arranged on the semiconductor chip 503. The semiconductor chip 503 corresponds to the semiconductor chip 103 in FIG. 1A, and the electrode pads P6 and P7 correspond to the electrode pads P1 and P2 in FIG. 1A, respectively.

On the package substrate 502, a stitch (first electrode) S61 is arranged outside of the semiconductor chip 503. More specifically, the stitch S61 is arranged to face a pair of electrode pads P6 and P7 with the side (side interposed between the electrode pads and the stitches) X of the semiconductor chip 503 as the axis. In this example, in the stitch S61, when it is assumed that a horizontal direction of the paper plane is a longitudinal direction, and a vertical direction of the paper plane is a width direction, a length of the longitudinal direction is longer than the stitch S11. For example, the length of the stitch S61 in the longitudinal direction is longer than the arrangement interval between the electrode pad P6 and the electrode pad P7. As a result, the stitch S61 can be coupled with any one of the electrode pads P6 and P7 through a bonding wire.

Also, on the package substrate 502, a stitch (second electrode) S71 is arranged at a position farther from the semiconductor chip 503 than the stitch S61 outside of the semiconductor chip 503. More specifically, the stitch S71 is arranged to face the pair of the electrode pads P6 and P7 at the position farther from the semiconductor chip 503 than the stitch S61 with the side X of the semiconductor chip 503 as the axis. In this example, the length of the stitch S71 in the longitudinal direction is longer than the stitch S11 like the stitch S61. For example, the length of the stitch S71 in the longitudinal direction is longer than the arrangement interval between the electrode pad P6 and the electrode pad P7. As a result, the stitch S71 can be coupled with any one of the electrode pads P6 and P7 through a bonding wire.

Further, the package substrate 502 is provided with a ball (first external electrode) B6 and a ball (second external electrode) B7 which can be coupled with the external circuit. For example, the balls B6 and B7 are attached on a rear side of the package substrate 502 in an array together with a plurality of other balls. The stitch S61 and the ball 36 which is the external electrode are coupled with each other through a wire (first wire) W61 arranged on the package substrate 502. The stitch S71 and the ball B7 which is the external electrode are coupled with each other through a wire (second wire) W71 arranged on the package substrate 502.

In the example of FIG. 10A, the electrode pad P6 on the semiconductor chip 503 and the stitch S61 are coupled with each other through a bonding wire BW6. The electrode pad P7 on the semiconductor chip 503 and the stitch S71 are coupled with each other through a bonding wire BW7. That is, in the example of FIG. 10A, the electrode pad P6 of the semiconductor chip 503 is allocated to the ball B6, and the electrode pad P7 of the semiconductor chip 503 is allocated to the ball B7.

On the other hand, in the example of FIG. 10B, the electrode pad P6 on the semiconductor chip 503 and the stitch S71 are coupled with each other through the bonding wire BW6. The electrode pad P7 on the semiconductor chip 503 and the stitch S61 are coupled with each other through a bonding wire BW7. That is, in the example of FIG. 10B, the electrode pad P7 of the semiconductor chip 503 is allocated to the ball 36, and the electrode pad P6 of the semiconductor chip 503 is allocated to the ball B7.

As illustrated in FIGS. 10A and 1033, the coupling target of the bonding wire BW6 is not limited to the stitch S61, but can be changed to the stitch S71. The coupling target of the bonding wire BW7 is not limited to the stitch S71, but can be changed to the stitch S61. For that reason, the electrode pads P6 and P7 on the semiconductor chip 503 which are allocated to the balls B6 and 37 can be changed by merely changing the coupling targets of the bonding wires BW6 and BW7.

The bonding wires that are coupled with the stitches (S61) electrically coupled with the ball B6 are also called “first bonding wires”. That is, the bonding wire BW6 coupled between the electrode pad P6 and the stitch S61, and the bonding wire BW7 coupled between the electrode pad P7 and the stitch S61, are also called “first bonding wires”. The electrode pad P6 and the stitch S61, or the electrode pad P7 and the stitch S61, are coupled by the first bonding wire.

The bonding wire connected to the stitch (S71) electrically connected to the ball B7 is also called “second bonding wire”. The bonding wire BW6 coupled between the electrode pad P6 and the stitch S71, and the bonding wire BW7 coupled between the electrode pad P7 and the stitch S71 are also called “second bonding wire”. The electrode pad P6 and the stitch S71, or the electrode pad P7 and the stitch S71 are coupled by the second bonding wire.

The first and second bonding wires are coupled by the respective different electrode pads.

In the examples of FIGS. 10A and 10B, both of the stitches S61 and S71 are arranged to face the pair of the electrode pads P6 and P7 with the side X of the semiconductor chip 503 as the axis. For that reason, the coupling targets of the bonding wires BW6 and BW7 can be changed without allowing the bonding wires BW6 and BW7 to intersect with each other.

In this way, the semiconductor device 501 according to this embodiment can change the electrode pads P6 and P7 of the semiconductor chip 503 which are allocated to the balls B6 and B7 which are the external balls with only a simple change in the coupling targets of the bonding wires BW6 to BW7 without allowing the bonding wires BW6 and BW7 to intersect with each other. In this situation, there is no need to newly add a bonding wire unlike the related art. For that reason, the semiconductor device 501 according to this embodiment can change the electrode pads P6 and P7 of the semiconductor chip 503 which are allocated to the balls B6 and B7 with any increase in the number of wires. With the use of the semiconductor device, for example, even if the external LSI is changed, there is no need to purposely change the package substrate for the purpose of reducing the wiring congestion.

The above-mentioned respective stitches S61 and S71 have a width larger than that of the wires W61 and W71 so as to be easily coupled with the bonding wires BW6 and BW7, and are distinguished from the wires per see.

The respective stitches (S61, S71) do not always need to be arranged to face the corresponding electrode pads (the pair of P6 and P7) with the side X of the semiconductor chip 503 as the axis as in the other embodiments. If the bonding wires (BW6, BW7) do not intersect with each other regardless of the coupling targets, the position at which the stitches are arranged can be appropriately changed. Also, the length of the respective stitches in the longitudinal direction does not always need to be longer than the arrangement interval of the electrode pad P6 and the electrode pad P7. Unless the bonding wires (BW6, BW7) intersect with each other regardless of the coupling targets, the length of the stitch in the longitudinal direction can be appropriately changed.

### Differences Between the Invention and Related Art

Subsequently, a description will be given of differences between the configuration of the present invention and the configurations disclosed in Japanese Unexamined Patent Publication No. 2002-237567 and the Japanese Unexamined Patent Publication No. 2010-103442.

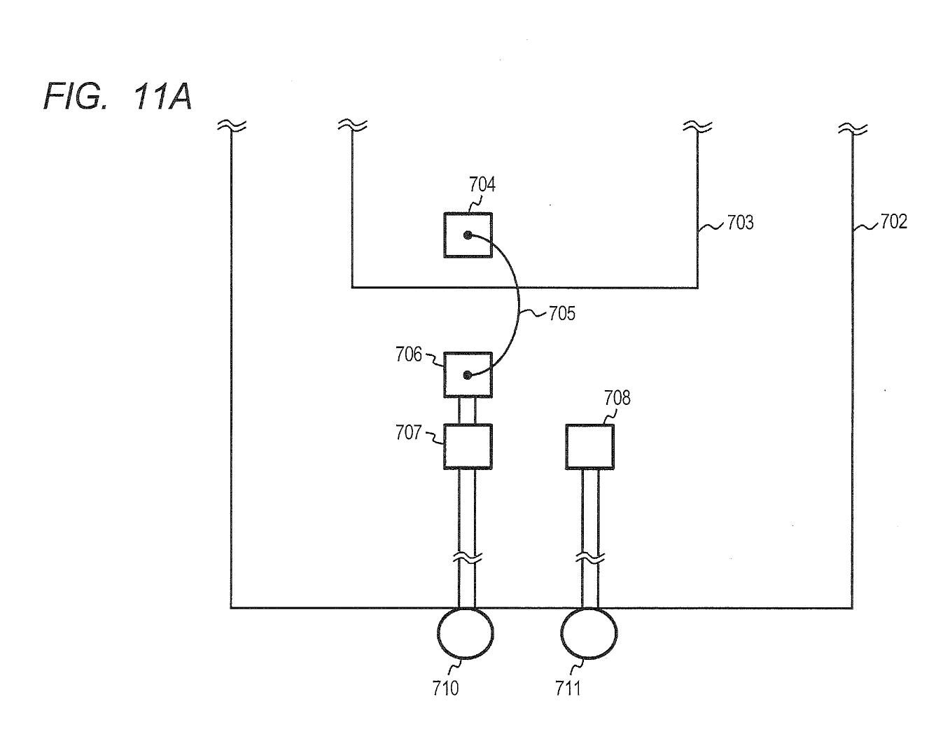

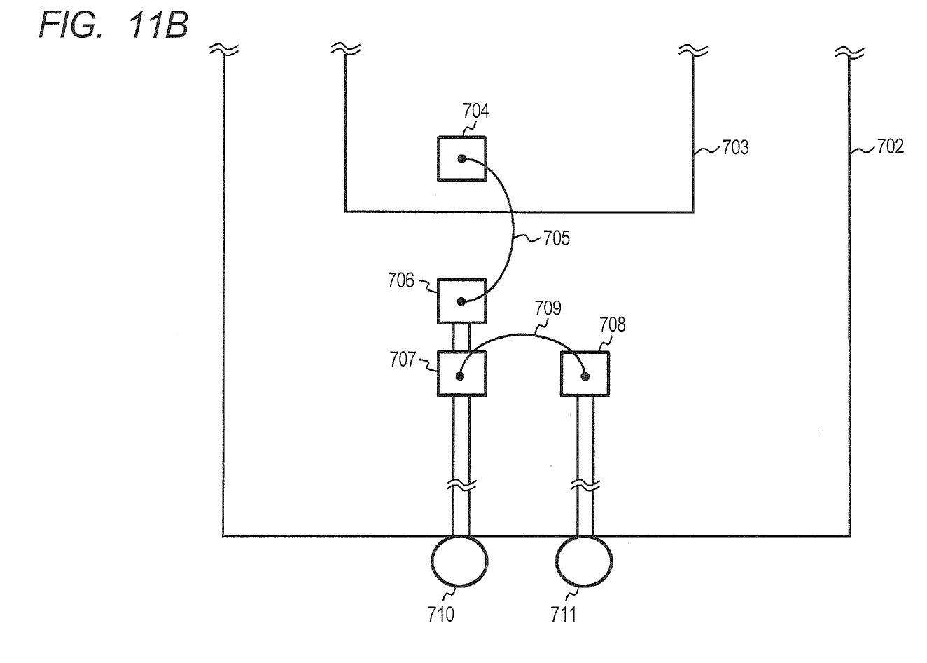

First, a description will be given of differences between the configuration disclosed in Japanese Unexamined Patent Publication No. 2002-237567 and the configuration of the present invention with reference to FIGS. 11A and 11B. FIGS. 11A and 11B redraw a part of the configuration disclosed in Japanese Unexamined Patent Publication No. 2002-237567 for the purpose of facilitating the comparison with the present invention.

As illustrated in FIG. 11A, a pad 704 is arrange on a first chip 703. The pad 704 is coupled with a stitch 706 disposed on a substrate 702. The stitch 706 is wired to an auxiliary stitch 707. The auxiliary stitch 707 is wired to a solder ball 710. An auxiliary stitch 708 is wired to a solder ball 711. That is, in FIG. 11A, a coupling target of the pad 704 on the first chip 703 is the solder ball 710.

If the coupling target of the pad 704 on the first chip 703 is to be changed to the solder ball 711, as illustrated in FIG. 11B, there is a need to couple the auxiliary stitch 707 and the auxiliary stitch 708 through a jump wire 709. For that reason, in the above related art, the number of wires is increased.

Further, in the above related art, because a coupling direction of the jump wire 709 between the auxiliary stitches 707 and 708 is different from a coupling direction of a bonding wire 705 between the pad 704 and the stitch 706, manufacturing processes are increased. Further, in the above related art, the allocation of the pads to the solder ball 710 can be changed.

On the other hand, in the present invention, the electrode pads of the semiconductor chip which are allocated to the balls can be changed without addition of a new wire such as the jump wire 709. For that reason as compared with the related art, an increase in the number of wires is suppressed, and an increase in the manufacturing processes is suppressed. Also, the allocation of the electrode pads to the balls can be also freely changed.

Subsequently, a description will be given of differences between the configuration disclosed in Japanese Unexamined Patent Publication No. 2010-103442 and the configuration of the present invention. The related art disclosed in Japanese Unexamined Patent Publication No. 2010-103442 pertains to a mounting substrate for electronic components which accept both of the wire bonding coupling and the flip chip coupling, and cannot freely change the allocation of the pads to the balls by changing the coupling target of the bonding wire. For that reason, when the external LSI is changed, there is a possibility that wiring between the chips is congested. Also, in order to reduce the wiring congestion, there is a need to change the package substrate.

On the other hand, in the present invention, the allocation of the electrode pads to the balls can be freely changed by only simply changing the coupling target of the bonding wire. For that reason, even when the external LSI is changed, there is no need to purposely change the package substrate for the purpose of reducing the wiring congestion.

As has been described above, in the semiconductor device according to the above first to fourth embodiments, the electrode pads of the semiconductor chip which are allocated to the balls which are the external balls can be changed with only a simple change in the coupling targets of the bonding wires without allowing the bonding wires to intersect with each other. In this situation, there is no need to newly add a bonding wire unlike the related art. For that reason, the semiconductor device 501 according to the above first to fourth embodiment can change the electrode pads of the semiconductor chip which are allocated to the balls with any increase in the number of wires. With the use of the semiconductor device, for example, even if the external LSI is changed, there is no need to purposely change the package substrate for the purpose of reducing the wiring congestion.

The present invention is not limited to the above first to fourth embodiments, but can be appropriately changed without departing from the subject matter of the invention. The above embodiments illustrate an example in which one or two auxiliary stitches (stitches S12, S13) are provided for one stitch (for example, stitch S11). However, the present invention is not limited to this configuration. Three or more auxiliary stitches may be provided for one stitch.

Also, in the above embodiment, an example in which one semiconductor chip is disposed on the package substrate has been described. However, the present invention is not limited to this configuration. The present invention can be appropriately changed to a configuration in which a plurality of semiconductor chips is stacked on the package substrate.

The semiconductor devices according to the above first to fourth embodiments can be effectively applied to goods having a possibility that the external LSI is changed by the client.

What is claimed is:

1. A semiconductor device comprising:
a semiconductor chip having first and second electrode pads; and
a package substrate on which the semiconductor chip is mounted, wherein the package substrate includes:
first and second electrodes;
a first external electrode that can be coupled with an external;
a first wire that couples the first electrode and the first external electrode; and
a second wire that couples the first electrode and the second electrode, and
wherein the package substrate further includes a first bonding wire that couples the first electrode and the first electrode pad, or the second electrode and the second electrode pad.

2. The semiconductor device according to claim 1,
wherein the first and second electrodes are arranged to face the first and second electrode pads, respectively.

3. The semiconductor device according to claim 1,
wherein the first and second electrodes are arranged in parallel to the first and second electrode pads, respectively.

4. The semiconductor device according to claim 1,
wherein the package substrate includes:
third and fourth electrodes;
a second external electrode that can be coupled with the external;
a third wire that couples the third electrode and the second external electrode; and
a fourth wire that couples the third electrode and the fourth electrode, and
wherein the package substrate further includes a second bonding wire that couples one of the third and fourth electrodes and the first electrode pad, or the other of the third and fourth electrodes and the second electrode pad.

5. The semiconductor device according to claim 4,
wherein the first and second bonding wires are coupled with the respective different electrode pads of the first and second electrode pads.

6. The semiconductor device according to claim 5,
wherein the first to fourth electrodes are arranged at positions where the first and second bonding wires do not intersect with each other.

7. The semiconductor device according to claim 4,
wherein one of the third and fourth electrodes is arranged to face the first electrode pad, and the other of the third and fourth electrodes is arranged to face the second electrode pad.

8. The semiconductor device according to claim 4,
wherein the third and fourth electrodes are arranged in parallel to the first and second electrode pads.

9. The semiconductor device according to claim 1,
wherein the semiconductor chip further includes a third electrode pad, wherein the package substrate further includes:
a fifth electrode; and
a fifth wire that couples the second electrode and the fifth electrode, and
wherein the first electrode and the first electrode pad, the second electrode and the second electrode pad, or the fifth electrode and the third electrode pad are coupled with each other through the first bonding wire.

10. The semiconductor device according to claim 9,
wherein the first, second, and fifth electrodes are arranged to face the first to third electrode pads, respectively.

11. The semiconductor device according to claim 9,
wherein the first, second, and fifth electrodes are arranged in parallel to the first to third electrode pads, respectively.

12. The semiconductor device according to claim 1,
wherein the semiconductor chip further includes fourth and fifth electrode pads disposed inside of the semiconductor chip more than the first and second electrode pads,
wherein the package substrate includes:
sixth and seventh electrodes;
a third external electrode that can be coupled with the external;
a sixth wire that couples the sixth electrode and the third external electrode; and
a seventh wire that couples the sixth electrode and the seventh electrode, and
wherein the package substrate further includes a third bonding wire that couples the sixth electrode and the fourth electrode pad, or the seventh electrode and the fifth electrode pad.

13. A semiconductor device comprising:
a semiconductor chip having first and second electrode pads; and
a package substrate on which the semiconductor chip is mounted,
wherein the package substrate includes:
a first electrode having a length corresponding to an arrangement interval between the first electrode pad and the second electrode pad;
a first external electrode that can be coupled with an external; and
a first wire that couples the first electrode and the first external electrode,
wherein the package substrate further includes a first bonding wire that couples the first electrode and the first electrode pad, or the first electrode and the second electrode pad.

14. The semiconductor device according to claim 13,
wherein a length of the first electrode is longer than an arrangement interval between the first electrode pad and the second electrode pad.

15. The semiconductor device according to claim 13,
wherein the first electrode is arranged to face a pair of the first and second electrode pads.

16. The semiconductor device according to claim 13,
wherein the package substrate includes:
a second electrode having a length corresponding to an arrangement interval between the first electrode pad and the second electrode pad;
a second external electrode that can be coupled with an external; and
a second wire that couples the second electrode and the second external electrode, and
wherein the package substrate further includes a second bonding wire that couples the second electrode and the first electrode pad, or the second electrode and the second electrode pad.

17. The semiconductor device according to claim 16,
wherein the first and second bonding wires are coupled with the respective different electrode pads of the first and second electrode pads.

18. The semiconductor device according to claim 17,
wherein the first and second electrodes are arranged at positions where the first and second bonding wires do not intersect with each other.

19. The semiconductor device according to claim 16,
wherein a length of the second electrode is longer than an arrangement interval between the first electrode pad and the second electrode pad.

20. The semiconductor device according to claim 16,
wherein the first electrode is arranged to face a pair of the first and second electrode pads, and
wherein the second electrode is arranged to face a pair of the first and second electrode pads.
